(19) United States
(12) Patent Application Publication
(10) Pub. No.: US 2008/0135942 A1
(43) Pub. Date: Jun. 12, 2008

(54) Semiconductor device, manufacturing method thereof, and SRAM cell

(75) Inventor: Sumito Minagawa, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/984,045

(22) Filed: Nov. 13, 2007

(30) Foreign Application Priority Data
Dec. 8, 2006 (JP) 2006-331620

(51) Int. Cl. H01L 27/11; H01L 21/336

(52) U.S. Cl. 257/368; 438/197; 257/E21.409; 257/E27.098

(57) ABSTRACT

An SRAM cell includes a semiconductor substrate; a first transistor formed in a main plane of the semiconductor substrate; a second transistor formed in the main plane of the semiconductor substrate; and a first wiring layer connecting a gate electrode of the first transistor with a diffusion region of the second transistor inside a first hole and formed to be spaced from the main plane of the semiconductor substrate inside the first hole.

### BACKGROUND OF THE INVENTION

1. Field of the Invention

This invention relates to a semiconductor device, a manufacturing method thereof, and an SRAM (Static Random Access Memory) cell.

2. Description of Related Art

In recent years, a semiconductor device is developed intensively. For example, it is strongly demanded to realize a high-density memory region in a cash memory that is integrated in a MPU (Micro Processing Unit).

Note that a structure of an SRAM cell has been developed from various viewpoints (See Japanese Unexamined Patent Application Publications No. 2002-198523, No. 10-214967, No. 2000-223713, and No. 2005-72577).

In order to miniaturize a functional element such as the SRAM cell, it is necessary to realize a high-density memory region. Regarding this point, there is a technique to connect a gate of a first transistor with a diffusion region of a second transistor via a common contact. Note that the common contact is realized by providing a hole (common hole) over a region where the gate of the first transistor and the diffusion region of the second transistor are formed, filling the hole with the electrical conductive material, and connecting the gate of the first transistor with the diffusion region of the second transistor via the electrical conductive material filled in the hole.

However, so-called contact leak may occur if the common contact is provided. This point is explained below with reference to FIG. 7.

FIG. 7 shows a view of a cross-sectional structure of a portion where the common contact is formed in the first and second transistors.

As shown in FIG. 7, a semiconductor device 500 includes a gate oxide film 501, a gate electrode 502, sidewall layers 504a and 504b, and a silicide layer 505 on a semiconductor substrate 520. A LDD (Lightly Doped Drain) region 507, a diffusion region 508, and STI (Shallow Trench Isolation) region 509 are formed in a main plane of the semiconductor substrate 520. Agate structure 503 includes the gate oxide film 501 and the gate electrode 502.

When a hole TH is formed in an insulating film 510, the sidewall layer 504a decreases in thickness from a dotted line to a solid line as schematically shown in FIG. 7. If an amount of decrease in thickness of the sidewall layer 504a exceeds a predetermined value, the main plane of the semiconductor substrate 520 may be exposed and a recessed portion 511 may be formed on the main plane of the semiconductor substrate 520. In this case, a wiring layer (plug) 506 is connected to a well region of the semiconductor substrate 520. Then current leaks from the wiring layer 506 to the well region of the semiconductor substrate 520.

Because of the decrease in thickness of the sidewall layer at the time the hole is formed, current may leak from the wiring layer to the well region of the semiconductor substrate at the portion where the common contact is formed.

### SUMMARY

In one embodiment, an SRAM cell includes a semiconductor substrate; a first transistor formed in a main plane of the semiconductor substrate; a second transistor formed in the main plane of the semiconductor substrate; and a first wiring layer connecting a gate electrode of the first transistor with a diffusion region of the second transistor inside a first hole and formed to be spaced from the main plane of the semiconductor substrate inside the first hole.

In another embodiment, a semiconductor device includes a gate electrode of a first transistor formed in a semiconductor substrate; a diffusion region of a second transistor formed in the semiconductor substrate; a spacer layer formed on the diffusion region; a first sidewall layer formed on a first side plane of the gate electrode; a second sidewall layer formed between the first sidewall layer and the spacer layer; an inter-layer insulating film having a common hole that is provided over the spacer layer and the gate electrode; and a plug formed inside the common hole, in which said second sidewall layer prevents the plug from contacting the substrate.

In still another embodiment, a manufacturing method of a semiconductor device includes forming a gate electrode of a first transistor in a semiconductor substrate; forming a diffusion region of a second transistor in the semiconductor substrate; forming a spacer layer on the diffusion region; forming a first sidewall layer on a first side plane of the gate electrode; forming a second sidewall layer between the first sidewall layer and the spacer layer; forming an inter-layer insulating film over the semiconductor substrate; forming a common hole in the inter-layer insulating film, the common hole is provided over the spacer layer and the gate electrode; and forming a plug in the common hole, the plug is spaced from the semiconductor substrate by the second sidewall layer.

It is suppressed that current leaks from a wiring layer (plug) to a well region of a semiconductor substrate at a region where a common contact is formed.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a schematic circuit diagram of an SRAM cell 10;

FIG. 2 is a schematic layout view of the SRAM cell 10;

FIG. 3 is a schematic view showing a sectional structure of a semiconductor device 20 (SRAM cell 10);

FIGS. 4A to 4F are schematic views showing manufacturing steps of the semiconductor device 20;

FIG. 5 is a schematic view showing a sectional structure of a semiconductor device 50;

FIGS. 6A to 6F are schematic views showing manufacturing steps of the semiconductor device 50; and

FIG. 7 is a schematic view showing a sectional structure of a related semiconductor device 500.

### DETAILED DESCRIPTION OF THE PREFERRED EMBODIMENTS

The invention will now be described herein with reference to illustrative embodiments. Those skilled in the art will recognize that many alternative embodiments can be accomplished using the teachings of the present invention and that the invention is not limited to the embodiments illustrated for explanatory purposes.

Embodiments of the present invention are explained below with reference to the drawings. Note that these embodiments are simplified for clarity. Therefore, it is not intended to narrow a scope of this invention based on the drawings. The drawings are provided only for explanation and not drawn to scale. Same components are denoted in same reference symbol and overlapping explanation is omitted.

### First Embodiment

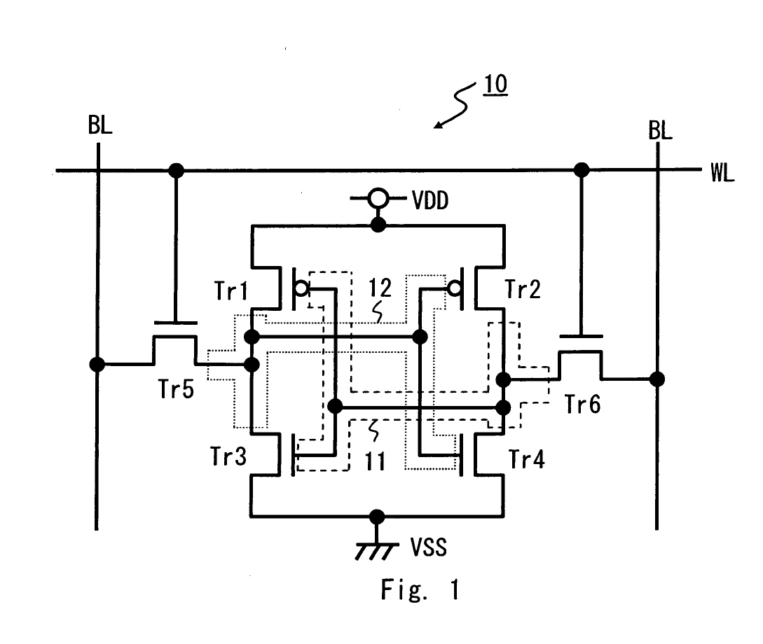

A circuit structure of an SRAM cell (memory cell) 10 is explained with a reference to FIG. 1.

As shown in FIG. 1, a load transistor Tr1 and a drive transistor Tr3 are connected between a power source potential VDD and a ground potential VSS in series. Gates of the load transistor Tr1 and the drive transistor Tr3 are connected to a node between a load transistor Tr2 and a drive transistor Tr4, and also connected to a transfer transistor Tr6. The transfer transistor Tr6 is connected to a node between the load transistor Tr2 and the drive transistor Tr4, and also connected to a bit line BL. A gate of the transfer transistor Tr6 is connected to a word line WL.

The load transistor Tr2 and the drive transistor Tr4 are connected between the power source potential VDD and the ground potential VSS in series, and forming a pair with the above-mentioned load transistor Tr1 and drive transistor Tr3. Gates of the load transistor Tr2 and the drive transistor Tr4 are connected to a node between the load transistor Tr1 and the drive transistor Tr3, and also connected to a transfer transistor Tr5. The transfer transistor Tr5 is connected to a node between the load transistor Tr1 and the drive transistor Tr3. The transfer transistor Tr5 is also connected to the bit line BL. A gate of the transfer transistor Tr5 is connected to the word line WL.

As shown in FIG. 1, a first memory node (cross node couple) 11 includes a wiring region extending from the gates of the transistors Tr1 and Tr3 to the drains of the transistors Tr2 and Tr4, and to the source of the transistor Tr6. On the other hand, a second memory node (cross node couple) 12, which forms a pair with the first memory node 11, includes a wiring region extends from the gates of the transistors Tr2 and Tr4 to the drains of the transistors Tr1 and Tr3, and to the source of the transistor Tr5. Note that these first and second memory nodes 11 and 12 are set to the potential of power source potential VDD or the ground potential VSS. A potential level of these first and second memory nodes 11 and 12 varies according to a signal that is to be memorized.

Note that a Flip-Flop circuit composed of the transistors Tr1, Tr3, Tr2, and Tr4 are included in the SRAM cell 10. The SRAM cell 10 is formed by adding the transistors Tr5 and Tr6 to the Flip-Flop circuit.

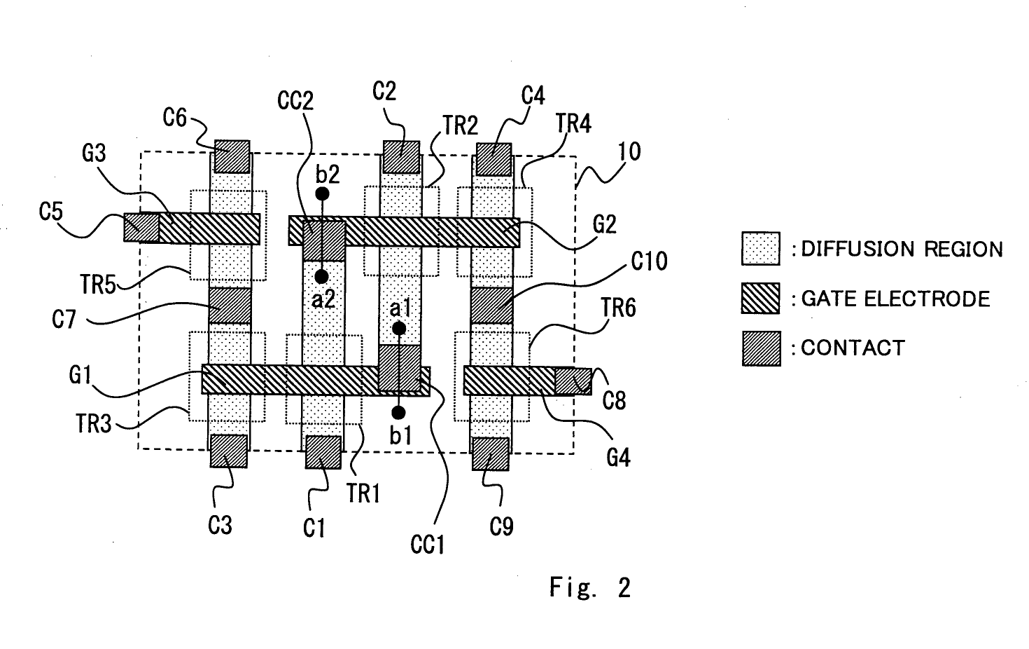

FIG. 2 shows a layout of the SRAM cell 10 according to this embodiment. As shown in FIG. 2, the SRAM cell 10 uses a common gate electrode G1 as each of the gate electrodes of the transistors Tr1 and Tr3. A common gate electrode G2 is used as each of gate electrodes of the transistors Tr2 and Tr4. The gate electrode G1 extends to a region over a drain region of the transistor Tr2. In same way, the gate electrode G2 extends to a region over a drain region of the transistor Tr1.

In this embodiment, two common contacts are formed in the SRAM cell 10. A common contact CC1 connects the gate electrodes of the transistors Tr1 and Tr3 with the drain region (diffusion region) of the transistor Tr2. A common contact CC2 connects the gate electrodes of the transistors Tr2 and Tr4 with the drain region (diffusion region) of the transistor Tr1.

Note that a source region of the transistor Tr1 is connected to a power supply potential VDD via a contact C1. A source region of the transistor Tr2 is connected to a power supply potential VDD via a contact C2. A source region of the transistor Tr3 is connected to a ground potential VSS via a contact C3. A source region of the transistor Tr4 is connected to the ground potential VSS via a contact C4.

A gate electrode G3 of the transistor Tr5 is connected to the word line WL via a contact C5. A drain region of the transistor Tr5 is connected to the bit line BL via a contact C6. A source region of the transistor Tr5 is connected to the above-mentioned common contact CC2 via a contact C7. Note that the drain region of the transistor Tr3 and the source region of the transistor Tr5 are connected in a common diffusion region. Therefore, the drain region of the transistor Tr3 is also connected to the above-mentioned common contact CC2 via the contact C7. The contact C7 and the common contact CC2 are connected in an upper wiring layer (not shown).

A gate electrode G4 of the transistor Tr6 is connected to the word line WL via a contact C8. A drain region of the transistor Tr6 is connected to the bit line BL via a contact C9. A source region of the transistor Tr6 is connected to the above-mentioned common contact CC1 via a contact C10. Note that the source region of the transistor Tr6 and a drain region of the transistor Tr4 are formed in a common diffusion region. Therefore, the drain region of the transistor Tr4 is also connected to the above-mentioned common contact CC1 via the contact C10. The contact C10 and the common contact CC1 are connected in the upper wiring layer (not shown).

The first memory node 11 of FIG. 1 includes the gate electrode G1, the common contact CC1, and the contact C10. The second memory node 12 of FIG. 1 includes the gate electrode G2, the common contact CC2, and the contact C7.

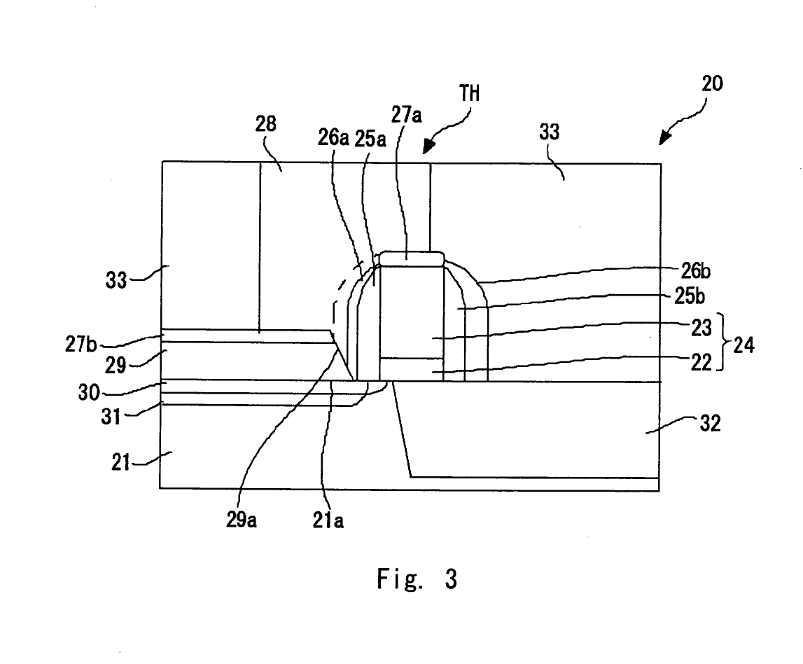

FIG. 3 shows a view showing a sectional structure of a portion of the SRAM cell 10 along a line a1-b1 of FIG. 2. Note that a sectional structure of a portion of the SRAM cell 10 along a line a2-b2 is same to a structure shown in FIG. 3. Therefore, overlapping explanation is omitted.

As shown in FIG. 3, a semiconductor device 20 (SRAM cell 10) includes a semiconductor substrate 21, a gate oxide film 22, a gate electrode 23, sidewall layers (a first sidewall layer) 25a and 25b, sidewall layers (a second sidewall layer) 26a and 26b, silicide layers 27a and 27b, a wiring layer (plug) 28, a spacer layer 29, and an insulating film (an inter-layer insulating film) 33. The wiring layer 28 is formed in a hole TH. A LDD (Lightly Doped Drain) region 30, a diffusion region 31, and STI (Shallow Trench Isolation) region 32 are formed in the semiconductor substrate 21.

A gate structure 24 is composed from the gate oxide film 22 and the gate electrode 23. This gate structure 24 is formed on a main plane 21a of the semiconductor substrate 21. The gate structure 24 is formed between the LDD region 30 and the STI region 32 which are formed in the main plane 21a of the semiconductor substrate 21. The gate oxide film 22 is made of oxide silicon (SiO2) or nitride silicon (SiN2) and so on, for example. This gate electrode 23 is made of a poly-silicon.

The sidewall layer 25a is formed on a side plane (a first side plane) at the LDD region 30 side of the gate structure 24. The sidewall layer 26a is also formed on the side plane at the LDD region 30 side of the gate structure 24. The sidewall layer 26a is formed over the sidewall layer 25a. In other words, a sidewall layer including two layers is formed on the first sidewall of the gate structure 24. Note that the sidewall layer 26a is formed on the sidewall layer 25a after the spacer layer 29 is formed as explained below.

The sidewall layer 25b is formed on a side surface (a second side surface) at the STI region 32 side of the gate structure 24. The sidewall layer 26b is also formed on the side surface at the STI region 32 side of the gate structure 24. The sidewall layer 26b is formed over the sidewall layer 25b. In other words, sidewall layers including two layers of the sidewall layers 25b and 26b are formed on the second sidewall of the gate structure 24.

The sidewall layers 25a and 25b are formed so as to mechanically support the gate electrode 23. The sidewall layers 26a and 26b are formed so as to mechanically support the gate electrode 23. The sidewall layers 25a, 25b, 26a, and 26b are made of oxide silicon (SiO2) or nitride silicon (SiN2) for example.

A thickness (a thickness in a direction that extends along the main plane 21a of the semiconductor substrate 21) of the sidewall layer 26a is thinner than that of the sidewall layer 26b. This is because the sidewall layer 26a is etched when the hole TH is formed in the insulating film 33 by chemical or physical etching.

The spacer layer 29 is formed on the main plane 21a of the semiconductor substrate 21. The spacer layer 29 is formed on the LDD region 30 (diffusion region 31) formed at the main plane 21a of the semiconductor substrate 21.

The spacer layer 29 is formed by epitaxial growth. In this epitaxial growth, silicon (Si) is grown on the main plane 21a of the semiconductor substrate 21 in liquid or gaseous phase. At this time, the spacer layer 29 is formed to have a slope portion (slope surface) 29a that faces the gate structure 24. Note that an impurity such as boron (B) is injected to the spacer layer 29 as mentioned below.

The silicide layer (contact layer) 27a is formed on the gate electrode 23 by so-called salicide step. In a same way, the silicide layer (contact layer) 27b is formed on the spacer layer 29 by salicide step. Note that the silicide layers 27a and 27b are formed by reacting metal with silicon in the salicide step. Enough electrical contact between the wiring layer 28 and the gate electrode 23 may be obtained by the silicide layer 27a. The silicide layer 27a secures electrical contact between the wiring layer 28 and the gate electrode 23. The silicide layer 27b secures enough electrical contact between the wiring layer 28 and the spacer layer 29.

The insulating film 33 is an inter-layer insulating film formed over the main plane 21a of the semiconductor substrate 21. The insulating film 33 is formed over the gate structure 24, the sidewall layers 25a and 26b, and the spacer layer 29. The insulating film 33 is formed over the silicide layers 27a and 27b. The hole TH is formed in the insulating film 33 by removing a portion (not shown) of the insulating film 33 over the gate structure 24, the sidewall layers 25a and 26a, the spacer layer 29, and the silicide layers 27a and 27b. The insulating film 33 is made of oxide silicon (SiO2) for example.

The wiring layer 28 is formed by filling an electrical conductive material (preferably a metal (aluminum (Al)) or polysilicon. The wiring layer 28 is formed over the gate structure 24, the sidewall layers 25a and 26a, and the spacer layer 29. The wiring layer 28 is also formed over the silicide layers 27a and 27b. The wiring layer 28 is formed by filling the electrical conductive material in the hole TH by a normal semiconductor process technique such as a sputtering. In this embodiment, the wiring layer 28 is formed between the spacer layer 29 and the sidewall layer 26a.

In this embodiment, the gate oxide film 22 (the gate structure 24), the sidewall layer 25a, the sidewall layer 26a, and the spacer 29 are formed on the main plane 21a of the semiconductor substrate 21 with substantially no space therebetween. In other words, the wiring layer 28 is formed to be spaced from the main plane 21a of the semiconductor substrate 21.

This is because the main plane 21a of the semiconductor substrate 21 is not exposed even though the slope portion 29a of the spacer layer 29 is exposed, when the hole TH is formed in the insulating film 33 formed over the main plane 21a of the semiconductor substrate 21 and the thickness of the sidewall layer 26a decreases from a dotted line to a solid line as schematically shown in FIG. 3.

Therefore, it is suppressed that the main plane 21a of the semiconductor substrate 21 is exposed and a recessed portion is formed at the main plane 21a of the semiconductor substrate 21. As a result, it is suppressed that current leaks from the wiring layer 28 to a well region of the semiconductor substrate 21.

Note that, in this embodiment, the wiring layer 28 contacts with the insulating film 33, the silicide layers 27a and 27b, the spacer layer 29, and the sidewall layer 26a in the hole TH. The wiring layer 28 may contact with the sidewall layer 25a according to an amount of the decrease in thickness of the sidewall layer 26a. However, it is suppressed that the wiring layer 28 contacts with the LDD region 30 by the spacer layer 29 formed on the main plane 21a of the semiconductor substrate 21.

The wiring layer 28 is formed inside a recessed portion that is defined by the slope portion 29a of the spacer layer 29 and the second sidewall layer 26a. The recessed portion defined by the slope portion 29a of the spacer layer 29 and the second sidewall layer 26a is spaced from the main plane 21a of the semiconductor substrate 21.

The sidewall layer 26a over the sidewall layer 25a contacts with the main plane 21a of the semiconductor substrate 21 and the spacer layer 29.

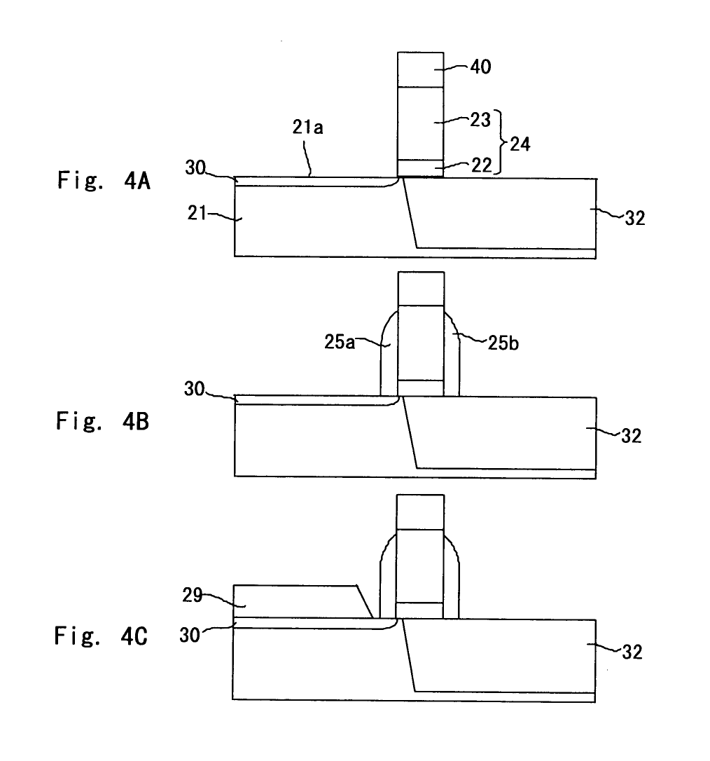

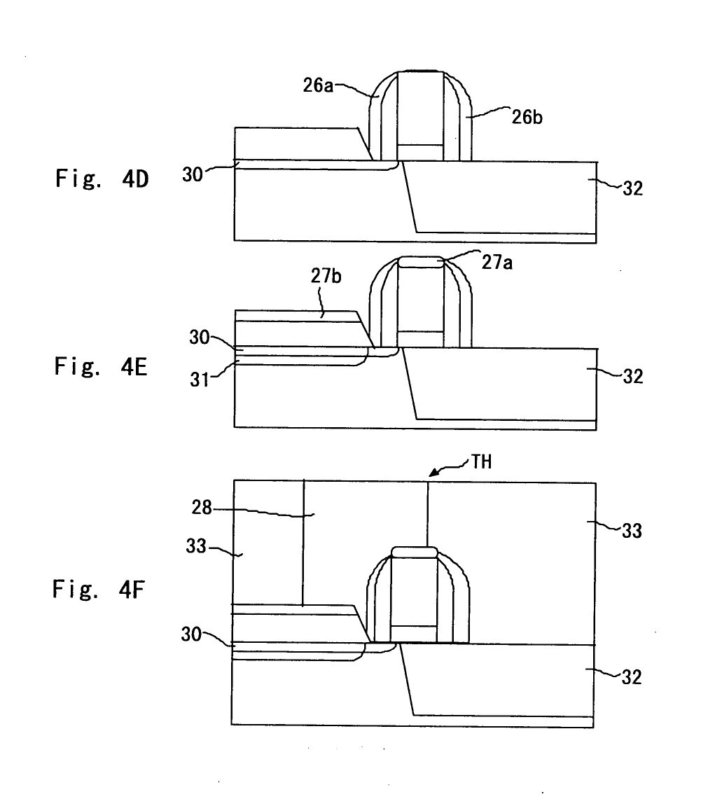

Next, a manufacturing step of the semiconductor device 20 is explained with reference to FIGS. 4A to 4F.

As shown in FIG. 4A, each of the LDD region 30 and the STI region 32 are formed on the main plane 21a of the semiconductor substrate 21 based on a normal semiconductor process technique. In a same way, the gate oxide film 22 is formed on the main plane 21a of the semiconductor substrate 21 and the gate electrode 23 on the gate oxide film 22. Then a resist layer 40 is formed on the gate electrode 23. The gate structure 24 is formed between the LDD region 30 and the STI region 32 which are formed on the main plane 21a of the semiconductor substrate 21.

Next, as shown in FIG. 4B, the sidewall layer 25a is formed on the side plane at the LDD region 30 side of the gate structure 24, and the sidewall layer 25b is formed on the side plane at the STI region 32 side of the gate structure 24.

Next, as shown in FIG. 4C, the spacer layer 29 is formed on the main plane 21a of the semiconductor substrate 21 by the epitaxial growth of silicon.

Next, as shown in FIG. 4D, the sidewall layer 26a is formed on the side plane at the LDD region 30 side of the gate structure 24, and the sidewall layer 26b is formed on the side plane at the STI region 32 side of the gate structure 24. The sidewall layer 26a is formed over the sidewall layer 25a. The sidewall layer 26b is formed over the sidewall layer 25b. The resist layer 40 is removed after forming the sidewall layers 26a and 26b.

Next, as shown in FIG. 4E, the diffusion region 31 is formed by diffusing impurities selectively. Then the salicide step is performed. That is, the silicide layer 27a is formed on an upper surface of the gate electrode 23 and the silicide layer 27b is formed on the spacer layer 29. Note that the impurities are injected to the spacer layer 29 by thermal diffusion of impurities.

Next, as shown in FIG. 4F, the insulating film 33 is formed over the main plane 21a of the semiconductor substrate 21. The insulating film 33 is partially removed to form the hole TH and then the wiring layer 28 is formed inside the hole TH.

In this embodiment, the hole TH is formed corresponding to a region where the gate oxide film 22 (the gate structure 24), the sidewall layer 25a, the sidewall layer 26a, and the spacer 29 are formed on the main plane 21a of the semiconductor substrate 21 with substantially no space therebetween. The wiring layer 28 is formed inside the hole TH by filling the electrical conductive material inside the hole TH. Therefore, it is suppressed that the wiring layer 28 contacts with the semiconductor substrate 21 directly. In other words, the wiring layer 28 is formed to be spaced from the main plane 21a of the semiconductor substrate.

This is because the main plane 21a of the semiconductor substrate 21 is not exposed even though the slope portion 29a of the spacer layer 29 is exposed when the hole TH is formed in the insulating film 33 and the thickness of the sidewall layer 26a decreases from a dotted line to a solid line as schematically shown in FIG. 3.

Therefore, it is suppressed that the main plane 21a of the semiconductor substrate 21 is exposed and the recessed portion is formed on the main plane 21a of the semiconductor substrate 21. As a result, it is suppressed that current leaks from the wiring layer 28 to a well region of the semiconductor substrate 21.

### Second Embodiment

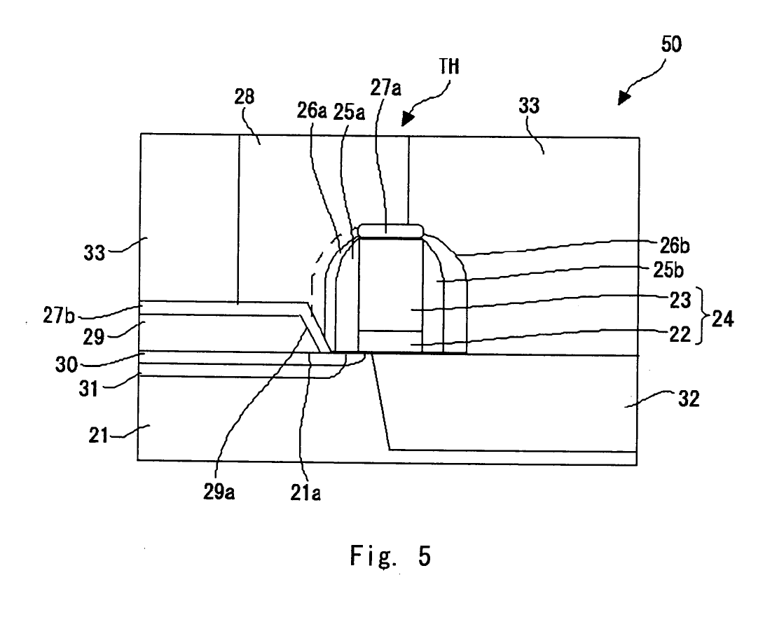

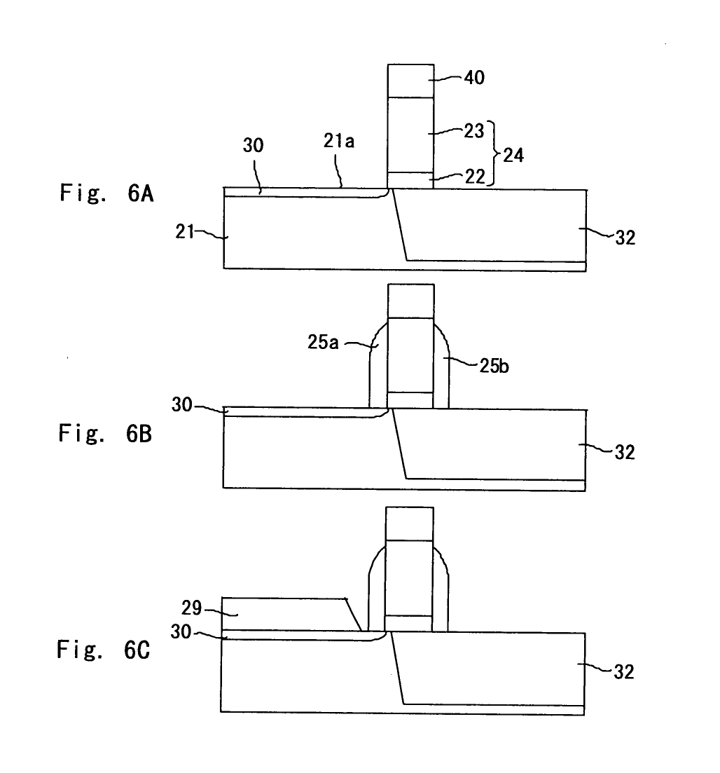

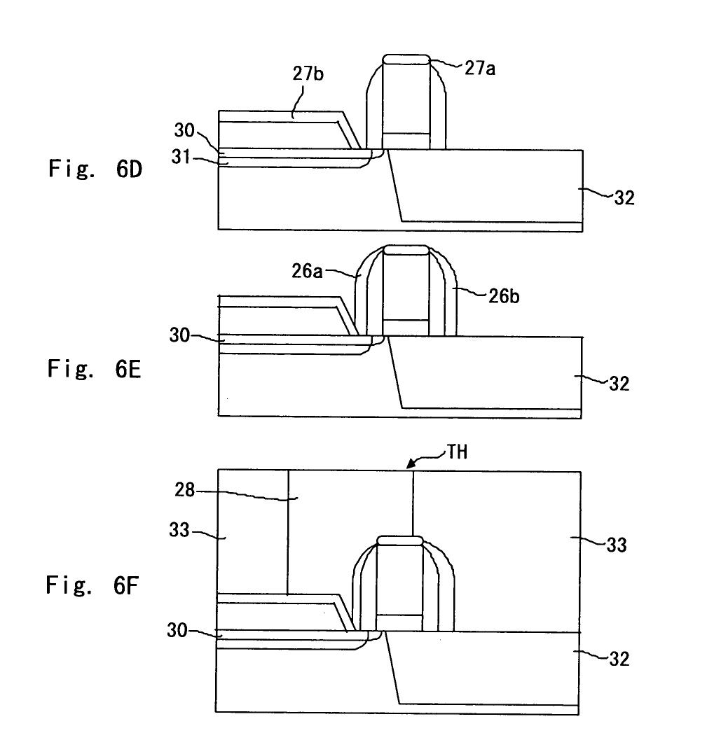

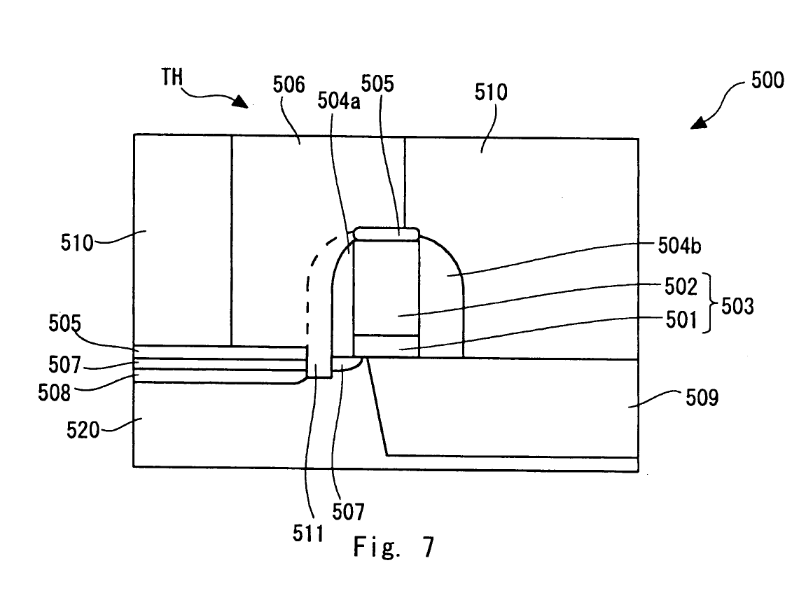

Next a second embodiment is explained with reference to FIGS. 5 and 6. FIG. 5 shows a view of schematic sectional structure of a semiconductor device 50 according to the second embodiment. Note that the semiconductor device 50 corresponds to the semiconductor device 20 of the first embodiment.

As shown in FIG. 5, the sidewall layer 26a is formed over the silicide layer 27b that is formed on the spacer layer 29. This is because the sidewall layers 26a and 26b are formed after the silicide layer 27b is formed in this semiconductor device 50 according to the second embodiment.

Note that the same effects explained as the first embodiment can also be realized in this embodiment.

In this embodiment, the gate oxide film 22 (the gate structure 24), the sidewall layer 25a, the sidewall layer 26a, the silicide layer 27b, and the spacer layer 29 are formed on the main plane 21a of the semiconductor substrate 21 with substantially no space therebetween. In other words, the wiring layer 28 is formed to be spaced from the main plane 21a of the semiconductor substrate 21. It is suppressed that the wiring layer 28 contacts with the main plane 21a of the semiconductor substrate 21.

This is because the main plane 21a of the semiconductor substrate 21 is not exposed even though the silicide layer 27b formed on the spacer layer 29 is exposed when the hole TH is formed in the insulating film 33 and the thickness of the sidewall layer 26a decreases from a dotted line to a solid line as schematically shown in FIG. 5.

Therefore, it is suppressed that the main plane 21a of the semiconductor substrate 21 is exposed and the recessed portion is formed at the main plane 21a of the semiconductor substrate 21. As a result, it is suppressed that current leaks from the wiring layer 28 to a well region of the semiconductor substrate 21.

Also compared with the first embodiment, the sidewall layer 26a is spaced from the main plane 21a of the semiconductor substrate 21 by a distance corresponding to the thickness of the silicide layer 27b. Therefore, it is suppressed more effectively that current leaks from the wiring layer 28 to the well region of the semiconductor substrate 21.

Note that the wiring layer 28 contacts with the insulating film 33, the silicide layers 27a and 27b, and the sidewall layer 26a. The wiring layer 28 may contact with the sidewall layer 25a according to an amount of decrease in thickness of the sidewall layer 26a. However, it is suppressed that the wiring layer 28 contacts with the LDD region 30 by the sidewall layer 26a formed between the spacer layer 29 and the sidewall layer 25a.

The wiring layer 28 is formed inside a recessed portion that is defined by the slope portion 29a of the spacer layer 29 and the second sidewall layer 26a. The recessed portion defined by the slope portion 29a of the spacer layer 29 and the second sidewall layer 26a is spaced from the main plane 21a of the semiconductor substrate 21.

Note that the wiring layer 28 is also formed inside a recessed portion that is defined by the silicide layer 27b formed on the slope portion 29a of the spacer layer 29 and the second sidewall layer 26a.

The sidewall layer 26a formed on the sidewall layer 25a contacts with the silicide layer 27b and the main plane 21a of the semiconductor substrate 21.

Manufacturing steps of the semiconductor device 50 is explained hereinafter with reference to FIGS. 4 to 6F. As mentioned above, the sidewall layers 26a and 26b are formed after the silicide layer 27b is formed.

As shown in FIG. 6A, each of the LDD region 30 and the STI region 32 are formed on the main plane 21a of the semiconductor substrate 21 based on a normal semiconductor process technique. In a same way, the gate oxide film 22 is formed on the main plane 21a of the semiconductor substrate 21 and the gate electrode 23 is formed on the gate oxide film 22. Then a resist layer 40 is formed on the gate electrode 23. The gate structure 24 is formed between the LDD region 30 and the STI region 32 which are formed on the main plane 21a of the semiconductor substrate 21.

Next, as shown in FIG. 6B, the sidewall layer 25a is formed on the side plane at the LDD region 30 side of the gate structure 24, and the sidewall layer 25b is formed on the side plane at the STI region 32 side of the gate structure 24.

Next, as shown in FIG. 6C, the spacer layer 29 is formed on the main plane 21a of the semiconductor substrate 21 by the epitaxial growth of silicon.

Next, as shown in FIG. 6D, the diffusion region 31 is formed by thermally diffusing impurities selectively. Then the resist layer 40 is removed and salicide step is performed. That is, the silicide layer 27 is formed on an upper surface of the gate electrode 23 and the silicide layer 27b is formed on the spacer layer 29.

Next, as shown in FIG. 6E, the sidewall layer 26a is formed on the side plane at the LDD region 30 side of the gate structure 24, and the sidewall layer 26b formed on the side plane at the STI region 32 side of the gate structure 24. The sidewall layer 26a is formed on the sidewall layer 25a. The sidewall layer 26b is formed on the sidewall layer 25b. The resist layer 40 is removed after the sidewall layers 26a and 26b are formed.

Next, as shown in FIG. 6F, the insulating film 33 is formed on the main plane 21a of the semiconductor substrate 21. The insulating film 33 is partially removed and the hole TH is formed and then the wiring layer 28 is formed inside the hole TH.

In this embodiment, the hole TH is formed corresponding to the region where the gate oxide film 22 (the gate structure 24), the sidewall layer 25a, the sidewall layer 26a, the silicide layer 27b, and the spacer layer 29 are formed on the main plane 21 of the semiconductor substrate 21 with substantially no space therebetween. The wiring layer 28 is formed inside the hole TH by filling the electrical conductive material inside the hole TH.

Therefore, it is suppressed that the wiring layer 28 contacts with the semiconductor substrate 21 directly. In other words, the wiring layer 28 is formed to be spaced from the main plane 21a of the semiconductor substrate 2. This is because the main plane 21a of the semiconductor substrate 21 is not exposed even though the silicide layer 27b formed on the spacer layer 29 is exposed when the hole TH is formed in the insulating film 33 and the thickness of the sidewall layer 26a decreases from a dotted line to a solid line as schematically shown in FIG. 5.

Therefore, it is suppressed that the main plane 21a of the semiconductor substrate 21 is exposed and the recessed portion is formed on the main plane 21a of the semiconductor substrate 21. As a result, it is suppressed that current leaks from the wiring layer 28 to a well region of the semiconductor substrate 21.

Compared with the first embodiment, the sidewall layer 26a is spaced from the main plane 21a of the semiconductor substrate 21 by a distance corresponding to the thickness of the silicide layer 27b. Therefore, it is suppressed more effectively that current leaks from the wiring layer 28 to the well region of the semiconductor substrate 21 in this semiconductor device 50 according to this embodiment.

It is apparent that the present invention is not limited to the above embodiment but it may be modified and changed without departing from the scope and spirit of the invention. This invention is not limited to the SRAM cell. This invention having the common contact may be applied to other usages such as Flip-Flop circuit and so on. The SRAM cell may be comprised from four transistors and not limited to be comprised from six transistors as explained. Manufacturing method is not limited to the way above explained. The sidewall layer may be formed by piling a plurality of layers.

What is claimed is:

1. An SRAM cell comprising:
a semiconductor substrate;
a first transistor formed in a main plane of the semiconductor substrate;
a second transistor formed in the main plane of the semiconductor substrate; and
a first wiring layer connecting a gate electrode of the first transistor with a diffusion region of the second transistor inside a first hole and formed to be spaced from the main plane of the semiconductor substrate inside the first hole.

2. The SRAM cell according to claim 1 further comprising:
a first sidewall layer formed on a first side plane at the diffusion region side of a gate structure of the first transistor; and
a spacer layer formed on the diffusion region of the second transistor, wherein
the gate structure of the first transistor, the first sidewall layer, and the spacer layer are formed on the main plane of the semiconductor substrate with substantially no space therebetween inside the first hole.

3. The SRAM cell according to claim 1 further comprising:
a first sidewall layer formed on a first side plane at the diffusion region side of a gate structure of the first transistor;
a spacer layer formed on the diffusion region of the second transistor; and
a contact layer formed on the spacer layer, wherein
the gate structure of the first transistor, the first sidewall layer, the spacer layer, and the contact layer are formed on the main plane of the semiconductor substrate with substantially no space therebetween inside the first hole.

4. The SRAM cell according to claim 1, wherein the first wiring layer is formed by filling an electrical conductive material in the first hole that is formed by removing a portion of an inter-layer insulating film formed over the main plane of the semiconductor substrate.

5. The SRAM cell according to claim 2, wherein a portion of the first wiring layer is interposed between the spacer layer and the first sidewall layer.

6. The SRAM cell according to claim 5, wherein the first sidewall layer includes two or more layers.

7. The SRAM cell according to claim 1 further comprising: a second sidewall layer formed on a second side plane of the gate structure, the second side plane opposing to the first side plane.

8. The SRAM cell according to claim 7, wherein the second sidewall layer is covered by an inter-layer insulating film formed over the main plane of the semiconductor substrate.

9. The SRAM cell according to claim 7, wherein the first sidewall layer is thinner than the second sidewall layer in a direction extending along the main plane of the semiconductor substrate.

10. The SRAM cell according to claim 1 further comprising:
a second wiring layer connecting a gate electrode of the second transistor with a diffusion region of the first transistor inside a second hole and spaced from the main plane of the semiconductor substrate.

11. A semiconductor device comprising:
a gate electrode of a first transistor formed in a semiconductor substrate;
a diffusion region of a second transistor formed in the semiconductor substrate;
a spacer layer formed on the diffusion region;
a first sidewall layer formed on a first side plane of the gate electrode;
a second sidewall layer formed between the first sidewall layer and the spacer layer;
an inter-layer insulating film having a common hole that is provided over the spacer layer and the gate electrode; and
a plug formed inside the common hole,
wherein said second sidewall layer prevents the plug from contacting the substrate.

12. The semiconductor device according to claim 11, wherein
the second sidewall layer is in contact with the first sidewall layer and the spacer layer.

13. The semiconductor device according to claim 12, wherein
a portion of the plug is formed inside a recessed portion that is defined by a slope surface of the spacer layer and the second sidewall layer.

14. The semiconductor device according to claim 11 further comprising:
a contact layer formed on the spacer layer, wherein
the second sidewall layer is in contact with the first sidewall layer and the contact layer.

15. The semiconductor device according to claim 14, wherein
a portion of the plug is formed inside a recessed portion that is defined by the contact layer formed on a slope surface of the spacer layer and the sidewall layer.

16. The semiconductor device according to claim 11, wherein the first and second transistors are included in a Flip-Flop circuit.

17. The semiconductor device according to claim 16, wherein the Flip-Flop circuit is included in an SRAM cell.

18. A manufacturing method of a semiconductor device comprising:
forming a gate electrode of a first transistor in a semiconductor substrate;
forming a diffusion region of a second transistor in the semiconductor substrate;
forming a spacer layer on the diffusion region;
forming a first sidewall layer on a first side plane of the gate electrode;
forming a second sidewall layer between the first sidewall layer and the spacer layer;
forming an inter-layer insulating film over the semiconductor substrate;
forming a common hole in the inter-layer insulating film, the common hole is provided over the spacer layer and the gate electrode; and
forming a plug in the common hole, the plug is spaced from the semiconductor substrate by the second sidewall layer.

19. The manufacturing method of the semiconductor device according to claim 18, wherein
the common hole is formed by removing a portion of the inter-layer insulating film and is formed over a region where the gate electrode, the first sidewall layer, the second sidewall layer, and the spacer layer are formed on a main plane of the semiconductor substrate with substantially no space therebetween.

20. The manufacturing method of the semiconductor device according to claim 18 further comprising:
forming a contact layer on the spacer layer,
wherein
the common hole is formed by removing a portion of the inter-layer insulating film and is formed over a region where the gate electrode, the first sidewall layer, the second sidewall layer, the contact layer, and the spacer layer are formed on a main plane of the semiconductor substrate with substantially no space therebetween.
